(19) United States
(12) Patent Application Publication
(10) Pub. No.: US 2009/0058477 A1
(43) Pub. Date: Mar. 5, 2009

(54) Method and system for reclocking a digital signal

(75) Inventor: John W. Curtis, Lakemont, GA (US)

Correspondence Address: BUCHANAN, INGERSOLL & ROONEY PC, POST OFFICE BOX 1404, ALEXANDRIA, VA, 22313-1404, US

(73) Assignee: PESA Switching Systems, Inc., Huntsville, AL (US)

(21) Appl. No.: 12/230,868

(22) Filed: Sep. 5, 2008

Related U.S. Application Data
(60) Provisional application No. 60/935,899, filed on Sep. 5, 2007.

(51) Int. Cl. H03L 7/00

(52) U.S. Cl. 327/145

(57) ABSTRACT

A method and system are disclosed for reclocking a digital time-based signal. An exemplary method includes receiving a digital signal output at a first clock rate. Data transitions of the received digital signal are measured using a master clock having a second clock rate. The digital signal is filtered to determine approximate edge positions of the data transitions. A tolerance is enforced between the approximate edge positions to reconstruct the digital signal. The reconstructed signal is output. The exemplary system for reclocking a digital time-based signal includes an input section, a processor and a reconstruction section.

This application claims priority to U.S. Provisional Application No. 60/935,899, filed on Sep. 5, 2007, the entire contents of which are hereby incorporated by reference.

### FIELD

The disclosed embodiments are directed to reclocking a digital time-based signal.

### BACKGROUND

Digital signals are known to include noise, such as jitter. The term “jitter” includes time, amplitude, frequency or phase-related spurious variations in interval, magnitude, frequency or phase of a signal. When jitter is present in a digital signal, a system receiving the signal may have difficulty determining edges of data transitions (i.e., from a high data signal to a low data signal). Edges are often used to determine the time interval of a signal, the magnitude of successive cycles, the frequency of successive pulses, and/or the phase of the frequency modulation of successive pulses referenced to the phase of a continuous oscillator.

To address jitter, it is known to “reclock” an incoming signal to a known clock signal that corresponds to the data rate of the incoming signal. Reclocking a self-clocking digital signal can involve applying analog equalizing to the received signal, recovering the clock from the signal, recovering the data, de-jittering the recovered clock, and retransmitting the data on the de-jittered clock. While commercial semiconductor parts exist for performing this function, most of them operate on a single signal. Although they are not individually expensive, the total cost of parts required for multiple channels can become significant, and the space consumed can grow linearly with channel count. Analog phase lock loop circuitry employed for recovering and de-jittering a clock from such a signal can be difficult to apply as multiple channels on a single semiconductor substrate. For those applications lacking the volume to apply custom integrated circuits, the single-channel commercial parts have been used.

It is known to sample a digital waveform using a fixed oscillator. There are known methods for recovering data from a self-clocking digital signal through the use of a fixed clock (e.g., a clock having a frequency four (4) to sixteen (16) times that of the clock used to construct the signal). These methods do not recover the clock. Instead, these methods generate a clock-enable signal, which indicates clock cycles of the fixed clock are associated with recovered data. This clock enable signal is related to the original clock. However, the clock enable signal and the original clock, having the same long-term average frequency, can possess jitter (e.g., up to 0.5 Unit Interval (UI) based on the ratio between the frequency of the original clock and that of the local fixed oscillator). This intrinsic jitter can be in addition to whatever jitter is on the digital signal at the time it is sampled.

### SUMMARY OF THE DISCLOSURE

A method and system are disclosed for reclocking a digital signal. An exemplary method includes receiving a digital signal output at a first clock rate. Data transitions of the received digital signal are measured using a master clock having a second clock rate. The digital signal is filtered to determine approximate edge positions of the data transitions. A tolerance is enforced between the approximate edge positions to reconstruct the digital signal. The reconstructed signal is output.

A disclosed, exemplary system for reclocking a digital time-based signal includes an input section for receiving digital signals and a master clock signal. A processor determines the data transitions of the received digital signals using the master clock signal. The processor filters the digital signal to determine approximate edge positions of the data transitions and enforces a tolerance between the edge positions. A reconstruction section reconstructs the digital signal using the edge positions within the enforced tolerance and outputs the reconstructed digital signal.

### BRIEF DESCRIPTION OF THE DRAWING FIGURES

Exemplary embodiments will be described with reference to the attached drawing figures:

FIG. 1 illustrates an exemplary block diagram for processing a digital audio signal according to a disclosed embodiment;

FIG. 2 is a waveform diagram illustrating various exemplary stages of a received data signal;

FIG. 3 illustrates an exemplary system for implementing an embodiment of the disclosed method; and

FIG. 4 illustrates an exemplary signal processing system for distributing audio and/or video data.

### DETAILED DESCRIPTION

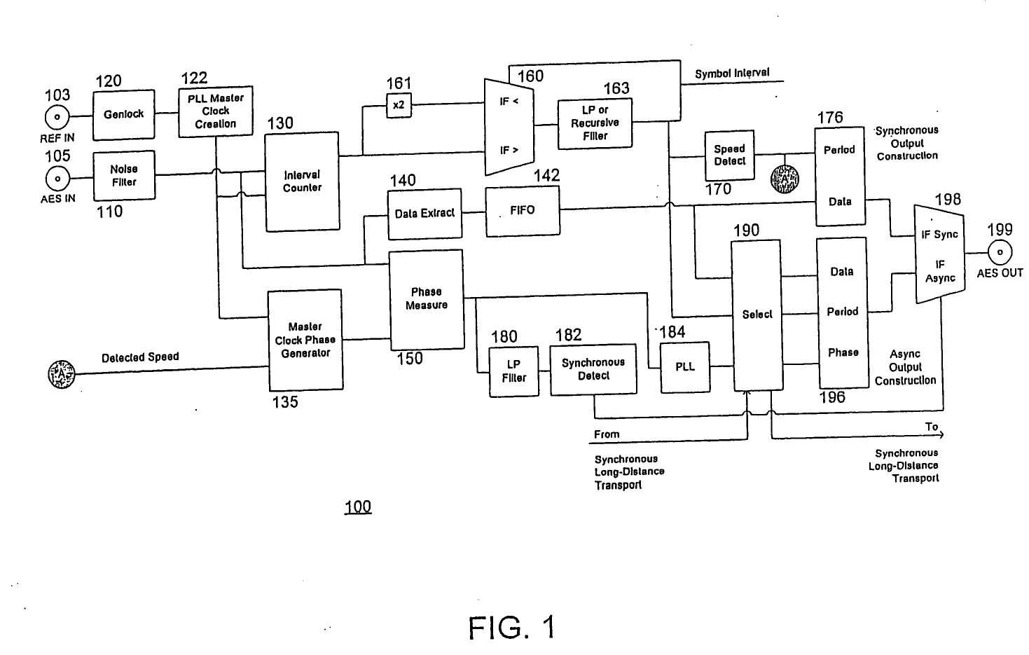

FIG. 1 illustrates an exemplary system for reclocking a digital audio signal. The system 100 receives signals on inputs 103 and 105. Input 103 receives a master or reference clock signal from a reference clock, for example, the system clock located in an audio/video production studio. Alternatively, a 27 MHz clock signal, for example, that is locked to the frame reference of the audio content can be used (e.g., a 27 MHz clock signal). The clock signal can be used to make the audio rate clocks and high speed transport clocks. Input 105 receives a digital audio signal at a first clock rate. The digital audio signal received on input 105 can be compliant with any desired standard, such as Audio Engineering Society-3 (AES3), although it is not required that the signal comply with a standard. The reconstructed signal is output.

The received audio signal can be filtered via noise filter 110, if desired. When the received input digital audio signal is filtered, it is forwarded to interval counter 130 for a determination of the bit rate of the received audio signal. Once the bit rate is determined, the signal output from the interval counter 130 is input into intermediate frequency device 160, which can have any number (e.g., 2 or more) inputs. One input to intermediate frequency device 160 can receive the signal from the interval counter 130, while a second input can be doubled or have a two times multiplier 161 that multiplies the signal output from the interval counter 130. Of course, other multiple values can be used. The output from the intermediate frequency device 160 is input in the recursive filter 163 which filters and outputs a symbol interval (i.e., edge interval) or bit rate value of the received digital audio signal. The intent is to normalize the edge interval between edges so the intervals can be averaged to determine the underlying rate.

On the other input 103, the reference clock is input to a phase lock loop master clock creation circuit 122. Master clock creation circuit 122 using the reference clock outputs a master clock signal to the master clock phase generator 135. The master clock phase generator 135 also receives a detected speed (i.e., symbol interval or bit rate). The detected speed is determined by speed detect circuit 170, which receives its input from the recursive filter 163.

Once the data speed detect circuit 170 detects the speed of the data, it outputs the detected speed to the synchronous output construction circuit 176 and to the master clock phase generator 135. The master clock phase generator 135 synthesizes an edge interval or data transition. A phase measurement by phase measurement circuit 150 of the master clock phase generator 135 determines whether the received audio signal has a phase difference from the master clock. The phase measurement circuit 150 receives the digital audio signal from the input 105 after it has been filtered by the noise filter 110. The phase measurement circuit 150 measures data transitions of the received digital signal relative to a master clock having a second clock rate.

The output of the phase measurement circuit 150 is input into a phase lock loop 184, into a low pass filter 180, and a synchronous detection circuit 182. The output of the synchronous detection circuit 182 is then input into the switch 198.

The digital signal is filtered to determine the approximate edge positions of the data transitions. The measurement of the edge position of transitions of the incoming signal is determined, for example, relative to a modulo counter running from the master clock that can be a high harmonic of the nominal clock rate of the digital signal. The received digital audio signal received via input 105 is also input into the data extract circuit 140, which buffers the extracted data in a first in first out (FIFO) register 142. If it is determined that the data is synchronous, the synchronous output construction circuit 176 reads the buffered data from the FIFO 142 and reconstructs the data based on the period determined by the speed detect circuit 170. Based on the output from the synchronous detection circuit 182, indicating synchronous data, the switch 198 is set to output the synchronous data, for example, without any further processing via output 199.

However, if the received digital audio signal is an asynchronous signal, the asynchronous signal is reconstructed by combining data extracted from the received digital audio signal based on the detected bit rate and the phase difference to output a signal synchronized to the reference clock. A tolerance is enforced between the approximate edge positions to reconstruct the digital signal with the same symbol rate as at the input, but through transmission paths and processing logic synchronous with the incoming reference clock. Since the received digital audio signal on input 105 is asynchronous, the phase measurement circuit 150 can detect a phase difference between the master clock phase (obtained from a combination of detected speed 170 and master clock 122) and the received digital audio signal.

The phase difference signal output from the phase measurement circuit 150 is output to two circuits. It is output to a phase locked loop circuit 184 and to a low pass filter 180. The phase lock loop circuit 184 removes any jitter from the phase difference signal output from the phase measurement circuit 150.

The output of the phase locked loop circuit 184 is a signal indicating phase difference information regarding the master clock and the received digital audio signal to select circuit 190. The select circuit 190 reads the data from FIFO 142, the symbol interval and signals indicating phase difference information, all of which is forwarded to the asynchronous output reconstruction circuit 196. The reconstructed signal which is synchronized with the master clock and substantially jitter free is output to switch 198 Alternately, switch 190 can select data transmitted in a similar format from other blocks and/or transmit the data, period and phase data to a similar circuit elsewhere.

Switch 198 outputs the reconstructed signal from the asynchronous output reconstruction circuit 196 based on a signal from synchronous detect circuit 182 that the received digital audio signal was asynchronous.

The nominal clock rate of an Audio Engineering Society (AES) signal is 12.288 MHz. A fixed oscillator of 184.320 MHz is a harmonic of this rate. If the incoming signal and the fixed oscillator are non-synchronous, it may be necessary to drop or add a clock of the fixed oscillator periodically to accurately synthesize the outgoing clock, but that rate (184.320 MHz) is sufficiently high that adding or dropping a clock will be below the 0.025 Unit Interval (UI) intrinsic jitter threshold required by the AES specification.

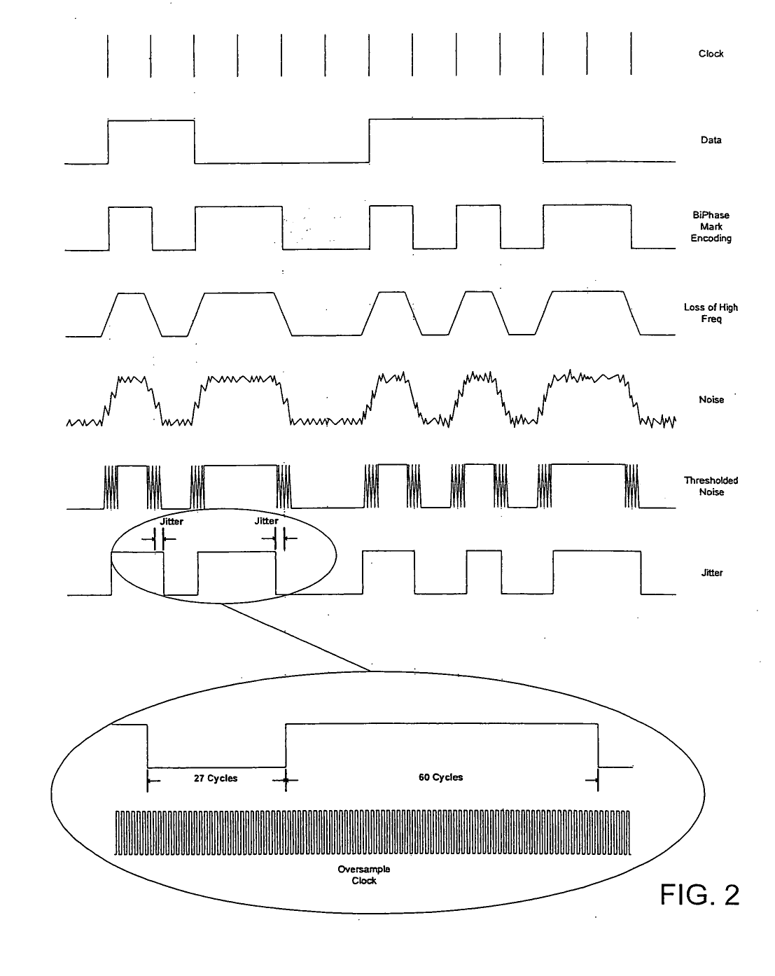

FIG. 2 illustrates the various signals at particular stages of the schematic circuit of FIG. 1. A data signal, which in the exemplary embodiment is a digital audio signal, can be a stereo digital audio signal complying with AES-3 standard is input. The data signal is received. The received signal can be used for self clocking purposes as the clock is implied from the data. Alternatively, a clock reference signal can be provided. Typically, the clock is necessary for compensation, for frequency equalization and/or reclocking, which is usually necessary when using analog phase locked loops to perform reclocking. Digital audio signals complying with the AES-3 standard can be produced for media content having accompanying surround sound or an alternative language. Surround sound, for example, creates a number of stereo pairs of AES signals.

Returning to FIG. 2, the digital audio data signal, e.g., stereo digital audio signal compliant with AES-3, is bi-phase mark encoded as shown in FIG. 2. As the bi-phase signal is processed, there is loss of some of the high frequency data as well as the injection of noise into the signal. The loss of high frequency data can be attributable to transmission path impedance, and noise can be introduced by the circuit components used to process the signal or received into the system via EMI interference. In order to recover the bi-phase mark encoded signal, the noise is thresholded. However, as shown in the thresholded noise signal, these spurious signal edges can create false transitions, such spurious edges are jitter. As shown by the jitter signal, the edge of the recovered bi-phase mark encoded signal can be slightly delayed or early from the original bi-phase encoded signal due to the jitter. If the jitter was not addressed, the data reconstruction circuit can mistake the timing of the bi-phase encoded data signal. In order for the recovered bi-phase mark encoded signal to be compliant with the AES-3 signal, the jitter must be within 0.025 Unit Intervals.

In an exemplary embodiment to ensure that the jitter of the bi-phase mark encoded data signal is compliant with the 0.025 UI for jitter, the jitter signal is compared to a high frequency over-sample clock to obtain the data rate of the bi-phase mark encoded data signal. It is also compared to a reference clock data rate. The data of the digital audio signal is separated from all other data formatting of the received digital signal. Only the data is transported, as bi-phase mark encoded data, through the exemplary embodiment.

In an exemplary circuit to implement FIG. 1, the inputs are presented to input I/O cells on an FPGA in DDR mode clocking at 184.32 MHz, for example. The resulting data stream is conducted to some configurable number of output I/O cells, also in DDR mode, where the original AES signal is reconstructed. The data stream can be filtered to remove noise and jitter.

In an exemplary embodiment, the data rate of the received digital audio signal above can be readily derived from a 27 MHz base clock, and is an even multiple of the clocking rates for 32 KHz, 48 KHz and 96 KHz AES data. See the exemplary table below:

| | | | | |
|---|---|---|---|---|
| Base Clock | 27,000,000 | | | |
| | 216,000,000 | Times 8 | | |
| | 2,880,000 | Over 25, Over 3 | | |
| Master Clock | 184,320,000 | Times 64 | | |
| Stereo Sample Rate | 32,000 | 44,100 | 48,000 | 96,000 |
| Bits per second | 2,048,000 | 2,822,400 | 3,072,000 | 6,144,000 |
| Clocks per second | 4,096,000 | 5,644,800 | 6,144,000 | 12,288,000 |
| Master Clocks per bit | 90.00 | 65.31 | 60.00 | 30.00 |
| Master Clocks per clk | 45.00 | 32.65 | 30.00 | 15.00 |

Although 44.1 KHz does not come out even, the overclocking rate can be sufficient that the intrinsic jitter this causes is less than the limit in the AES3 standard. Exemplary jitter requirements can be summarized as follows:

| | | |
|---|---|---|
| | 44100 | Hz |
| UI = | 177.154195 | nS |
| 0.025 UI = | 4.428854875 | nS |
| | 96000 | Hz |
| UI = | 81.38020833 | nS |
| 0.025 UI = | 2.034505208 | nS |
| | 184,320,000 | Hz Clk |
| Period | 5.425347222 | nS |
| Half Period. | 2.712673611 | nS |

Since the I/O cells of the FPGA are operating in DDR mode, the specified jitter limit is compared to the half-period of the master clock. The intrinsic jitter for the 96 KHz signal is somewhat over the limit, but would be insignificant if the audio were synchronous with the master clock.

Alternately, a higher speed clock, e.g., 276.48 MHz, can be used. See table below:

| | | | | |
|---|---|---|---|---|
| Base Clock | 27,000,000 | | | |
| | 216,000,000 | Times 8 | | |
| | 8,640,000 | Over 25 | | |
| Master Clock | 276,480,000 | Times 32 | | |
| Stereo Sample Rate | 32,000 | 44,100 | 48,000 | 96,000 |
| Bits per second | 2,048,000 | 2,822,400 | 3,072,000 | 6,144,000 |
| Clocks per second | 4,096,000 | 5,644,800 | 6,144,000 | 12,288,000 |
| Master Clocks per bit | 135.00 | 97.96 | 90.00 | 45.00 |
| Master Clocks per clk | 67.50 | 48.98 | 45.00 | 22.50 |

The fact that the number of master clocks per the received digital audio signal clock, e.g., AES, is fractional is acceptable since in DDR mode data moves on the half clock. In this case, a higher performance FPGA may be required, but the jitter limit is satisfied. See below:

| | | |
|---|---|---|
| | 44100 | Hz |
| UI = | 177.154195 | nS |
| 0.025UI = | 4.428854875 | nS |
| | 96000 | Hz |
| UI = | 81.38020833 | nS |
| 0.025UI = | 2.034505208 | nS |
| | 276,480,000 | Hz Clk |
| Period | 3.616898148 | nS |
| Half Per. | 1.808449074 | nS |

The exemplary method for substantially limiting jitter and to some extent equalizing the signal enforces the positioning of data transition edges at even multiples of the clock counts as shown in the table above, for example. For synchronous signals, this is fairly simple. Once an incoming transition is located, all succeeding transitions will naturally fall at even multiples of the master clock. A windowing function can be built that predicts where succeeding edges are expected. This will work even at 44.1 KHz. Even though the number of master clocks per received digital audio signal clock, such as an AES signal clock, for example, is not a whole number, the number of master clocks for 49 AES clocks, for example, is a whole number. For non-synchronous signals, the same strategy can be used except that the windowing function can be allowed to drift, for example, no more than one master clock at a time to keep the window aligned with the incoming data. Although, techniques can be used that allow more or less drift.

The signal processing in the synchronous case can be done by piping the data through a shift register so that patterns in the data stream can be observed. Once the edges are located, a counter is reset each time the next edge is expected and the data in the window can, for example, be uniformly replaced by a filtered version of the same data. One likely possibility is simply replacing the data with a majority vote of all the bits within the window.

Since the windows vary in size from 15 clocks to 90 clocks, the same result can be gained by some seven bit counters feeding some seven bit comparators.

In the asynchronous case, the counter for expected edges will require a facility for being reset a count early or a count late as it is determined that the incoming data edges have drifted with respect to the window.

Once the windowing function is in place, converting the data stream to and from AES, received digital audio signal, data packets, for example, is reasonably straightforward. Downstream of the jitter filter, the bi-phase data can be extracted directly from the bit replacement function and readily converted to binary AES data. This can be performed at data extraction 140. Likewise, if there is a desire to reconstruct the data stream from clock and data, a user uses the windowing function to track the clock, then convert the incoming data back to its bi-phase form and insert it instead of the filter result to the bit replacement function at, for example, block 196.

In the event that a signal was detected that showed no signs of having standard sample rates, the windowing and replacement function can be disabled and the signal passed. There would be no jitter improvement, but at least there would be a signal.

Within the context of AES distribution amplifiers, the following exemplary configurations can be implemented:
1× of 1 in by 7 out (8 BNC total)
2× of 1 in by 3 out (8 BNC total)
1× of 1 in by 15 out (16 BNC total)
2× of 1 in by 7 out (16 BNC total)
4× of 1 in by 3 out (16 BNC total)
4× of 1 in by 2 out plus 1× of 1 in by 3 out (16 BNC total)

Since the data can be recovered, it will be possible to monitor signal presence, sample rate and all of the status bits on any of the inputs. Since drift in the windowing function can be detected, it will be possible to monitor whether any input is synchronous with genlock.

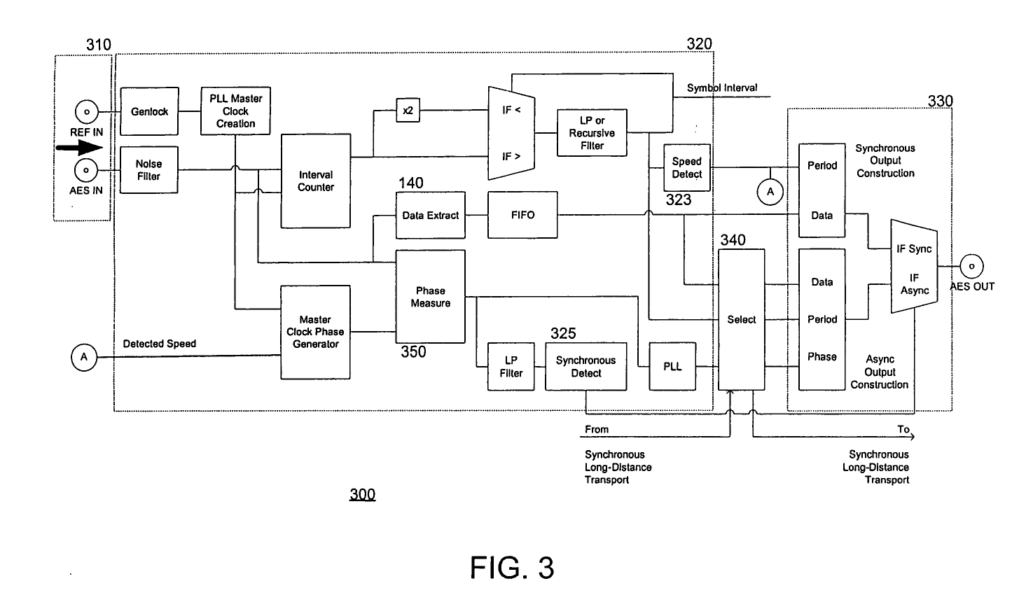

FIG. 3 illustrates an exemplary system for implementing the reclocking method. A system 300 for reclocking a digital time-based signal includes an input section 310, a processor 320, a reconstruction section 330 and a select section 340.

The input section 310 includes inputs for receiving multiple digital signals and a master clock signal. The processor 320 determines the data transitions of the received digital signals using the master clock signal. The processor 320 filters the digital signal to determine approximate edge positions of the data transitions. The processor 320 enforces a tolerance between the edge positions. A reconstruction section 330 reconstructs the digital signal using the edge positions within the enforced tolerance and outputs the reconstructed digital signal.

When the processor 320 determines that the data is synchronous, the reconstruction section 330 reads the buffered data from a FIFO 321 of the processor 320. The data is reconstructed based on a period determined by a speed detect circuit 323. Based on the output from the synchronous detection circuit 325, indicating synchronous data, the reconstruction section 330 is set to output the synchronous data.

However, if the received digital audio signal is an asynchronous signal, the asynchronous signal is reconstructed by combining data extracted from the received digital audio signal based on the detected bit rate and the phase difference to output a signal synchronized to the reference clock. The synchronized signal is synchronous with the incoming reference clock. Since the received digital audio signal on input section 310 is asynchronous, a phase measurement circuit 350 in processor 320 detects a phase difference between the detected speed (obtained from the speed detect circuit 323) of the received digital audio signal. Using this information, the reconstruction section 330 outputs the reconstructed signal based on a signal from synchronous detect circuit 325 that the received digital audio signal was asynchronous.

The select section 340 reads the data from FIFO 142, the symbol interval and signals indicating phase difference information, all of which is forwarded to the reconstruction section 330. Alternatively, the select section 340 can select data transmitted in a similar format from other blocks and/or transmit the data, period and phase data to a similar circuit elsewhere.

Beyond the distribution amplifier category, there are a number of other potential applications for this process. On the basis of the master clock rate above, it is possible to consolidate data from up to 36 sets of 48 KHz AES pairs onto a single I/O pin for transport off-board using a four-times oversampling technique that eliminates the need for clock recovery at the receiver. With the inclusion of this capability, individual boards can be cascaded to form a router of capacity 8 by 8 up to 40 by 40 with no incremental hardware added to the basic FPGA used for processing the AES signals. This limit is based on a transmission path at 270 Mbits that is readily achievable on the basic pins of a current generation FPGA. With a higher capacity channel, the size of the distributed router thus formed would grow linearly.

The system can be implemented in hardware and/or software. For example, a Field Programmable Gate Array (FPGA), can be used to clock data at rates above 1 GHz with input/Output (I/O) data rates up to 400 MHz.

If the received data representing the AES samples is structured so that it contains the channel number of the source and contains the position of the jitter removal window relative to a stable clock window, asynchronous data can be reconstructed as easily as synchronous. In other words, the router formed above could route asynchronous data without resampling as easily as it could handle synchronous data.

Using the same strategy, it would be possible to consolidate these groupings of AES channels onto higher speed copper or fiber optic transport to form a distributed router or a remote-DA. Given a high enough speed transport, these boards could be used in the same frame with video boards to combine video and audio transport to a remote frame. By changing the nature of the board doing the consolidation, the same strategy can be used as part of a distributed routing system (DRS) network. This would allow all the boards in the frame to function as elements of a mixed-mode embedded and discrete router.

A distributed routing system network as described in co-pending U.S. patent application Ser. No. 11/785,245 and U.S. Provisional Application Ser. No. 60/907,704 can be used to consolidate groupings of AES channels onto higher speed copper or fiber optic transport to form a distributed router or a remote-DA. The entire contents of both U.S. patent application Ser. No. 11/785,245 and U.S. Provisional Patent Application Ser. No. 60/907,704, are hereby incorporated by reference.

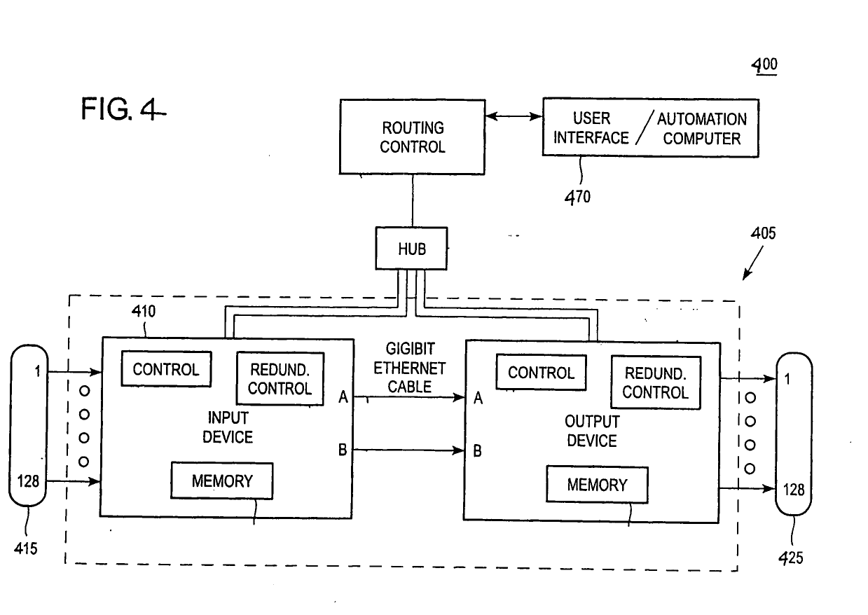

FIG. 4 illustrates a signal processing system 400 for distributing audio and/or video data. A signal processing system 400 comprises an input device 410, a user interface 470, and an output device 425. The signal processing system 400 comprises an input device 410 for receiving audio and/or video data from multiple input sources over multiple input paths 415 having inputs 1-128. The inputs can be 128 AES (AES3) audio inputs and for combining the data from the plural input paths 415 into serial data of a serialized data block. The AES inputs can be received and transmitted as audio pairs on unbalanced BNC connectors or 64 BNC connectors. The input sources need not be in parallel, but rather, can be located anywhere (e.g., separated by any suitable distance). Other connector options will be apparent to those skilled in the art.

Inputs and outputs can be AES unbalanced inputs or outputs, or any suitable inputs/outputs, or connectors, such as BNC connectors. Analog input signals are routed in the system by, for example, converting them to digital samples in input modules so that they can be routed as digital signals through the DRS. In an exemplary embodiment, the signals can conform to the AES standard, whether digital inputs, or analog inputs that are converted from analog to AES digital signals. The output signals can be output as digital signals (e.g., AES digital signals or converted to analog prior to output).

Implementing a distributed routing system as illustrated in FIG. 4, the distributed routing system receives data at a plurality of input devices and combines the received data into serial data of a serialized data block. The serial data contained in the serialized data block is reordered and a first portion of the serial data in the serialized data block is distributed to a first output path and a second portion of the serial data of the serialized data block is distributed to a second output path.

An exemplary embodiment can be implemented using a circuit board provisioned with 16 digital audio ports which can be individually configured for input or output providing maximum flexibility in the configuration of a distribution amp. Depending on the I/O board chosen, it will meet either the AES-3 specification for digital audio over twisted pair, or the AES-3id specification for digital audio over 75 ohm coaxial cable. In addition to the AES ports, the current board has, for example, four bi-directional high-speed ports that connect it to the two adjacent slots and the two special slots of the frame.

The basic clock for the exemplary board can be a 27 MHz genlock clock that is locked to the frame reference. From that clock any or all of the audio rate clocks and the high-speed transport clocks can be made.

While the invention has been shown and described with particular reference to various embodiments thereof, it will be understood that variations and modifications in form and details may be made therein without departing from the spirit and scope of the invention as defined in the appended claims.

What is claimed is:

1. A method for reclocking a time-based digital signal, comprising:
receiving a digital signal output at a first clock rate;
measuring data transitions of the received digital signal using a master clock having a second clock rate; and
filtering the digital signal to determine approximate edge positions of the data transitions;
enforcing a tolerance between the approximate edge positions to reconstruct the digital signal; and
outputting the reconstructed signal.

2. The method of claim 1, wherein the measuring is performed using a modulo counter operating at the second clock rate.

3. The method of claim 1, wherein the second clock rate is higher than the first clock rate.

4. The method of claim 1, wherein the second clock rate is a harmonic of the first clock rate.

5. The method of claim 2, wherein the tolerance is based on a number of counts from the modulo counter.

6. The method of claim 5, wherein the modulo counter is reset each time an edge is expected.

7. The method of claim 1, wherein the measuring comprises generating a master clock from a reference clock based on the detected bit rate.

8. The method of claim 1, wherein the filtering comprises:
using a windowing function having a window around a portion of the digital audio signal, wherein the window drifts one master clock cycle at a time to keep the window of the windowing function aligned with incoming data of the digital audio signal.

9. The method of claim 8, comprising:
replacing data contained in the window with data that has been reconstructed.

10. The method of claim 1, comprising:
receiving a digital audio signal, and extracting data from the received signal; and
determining a bit rate of the received digital audio signal.

11. The method of claim 1, wherein the filtering comprises:
determining a phase difference between the received digital audio signal and the master clock.

12. The method of claim 1, wherein the enforcing comprises:
maintaining, based on the phase difference, a master clock data rate to substantially correspond to data transitions of the received digital audio signal.

13. The method of claim 1, wherein the outputting comprises:
determining whether the received digital audio signal is an asynchronous signal; and
when the digital audio signal is asynchronous, reconstructing the digital audio signal by combining the data extracted from the received digital audio signal using the bit rate and the phase difference to output a reconstructed signal, which is synchronous with the reference clock.

14. The method of claim 1, wherein the digital time-based signal is an audio signal compliant with Audio Engineering Society (AES-3) Specification.

15. A system for reclocking a digital time-based signal, comprising:
an input section for receiving digital signals and a master clock signal;
a processor for determining the data transitions of the received digital signals using the master clock signal, filtering the digital signal to determine approximate edge positions of the data transitions and enforcing a tolerance between the edge positions; and
a reconstruction section for reconstructing the digital signal using the edge positions within the enforced tolerance and outputting the reconstructed digital signal.

16. The system of claim 15, comprising:
a select section for reading the data from a FIFO, a symbol interval and signals indicating phase difference information and forwarding the read information to the reconstruction section.
